(19) United States
(12) Patent Application Publication
(10) Pub. No.: US 2025/0379183 A1
(43) Pub. Date: Dec. 11, 2025

(54) METHOD FOR PRODUCING AT LEAST ONE SEMICONDUCTOR DEVICE AND SEMICONDUCTOR DEVICE

(71) Applicant: ams-OSRAM International GmbH, Regensburg (DE)

(72) Inventors: Michael Huber, Bad Abbach (DE); Mathias Wendt, Hausen (DE); Helena Doblinger, Regensburg (DE)

(21) Appl. No.: 18/873,679

(22) PCT Filed: Jun. 13, 2023
(86) PCT No.: PCT/EP2023/065792

§ 371 Date: Dec. 10, 2024

(30) Foreign Application Priority Data
Jun. 14, 2022 (DE) 10 2022 114 880.7

(51) Int. Cl. H01L 23/00

(52) U.S. Cl. CPC H01L 24/80; H01L 24/05; H01L 2224/05111; H01L 2224/05155; H01L 2224/05164; H01L 2224/05169; H01L 2224/05644; H01L 2224/8081

(57) ABSTRACT

In an embodiment a semiconductor device includes a semiconductor body and a carrier, wherein the semiconductor body is connected to the carrier by at least one solder joint, wherein at least one lateral surface of the at least one solder joint is free of traces of a cutting process, wherein the solder joint includes an alloy having a first and a second metal, wherein a concentrations of the first metal and the second metal in the alloy are in a non-eutectic ratio, and wherein the semiconductor device is a thin-film device in which a growth substrate of the semiconductor body is at least largely removed.

### CROSS-REFERENCE TO RELATED APPLICATIONS

This patent application is a national phase filing under section 371 of PCT/EP2023/065792, filed Jun. 13, 2023, which claims the priority of German patent application no. 102022114880.7, filed Jun. 14, 2022, each of which is incorporated herein by reference in its entirety.

### TECHNICAL FIELD

A method for producing at least one semiconductor device is specified. Furthermore, a semiconductor device is specified.

### SUMMARY

Embodiments provide a method for producing at least one semiconductor device which allows a semiconductor device with various geometrical shapes to be produced. Further embodiments provide a semiconductor device produced with such a method.

According to at least one embodiment, the method comprises a step of providing a first element. A first solder structure is arranged on the first element. Furthermore, a second element is provided. A second solder structure is arranged on the second element.

The first and/or second element are, for example, each a wafer or each comprise a wafer. The first and/or the second solder structure may be arranged on a main side of the respective element. For example, the first and/or the second solder structure cover a major part of the side of the respective element on which it is applied.

The first and the second solder structure comprise, in particular, metal. The first and/or the second solder structure may comprise or consist of a plurality of layers stacked above each other. The layers may comprise different materials.

According to at least one embodiment, at least the first solder structure comprises a plurality of solder islands which are laterally spaced from each other and separated from each other by at least one trench. The at least one trench extends from an outer surface of the first solder structure in a vertical direction towards the first element.

The solder islands may each comprise or consist of metal, e.g. a stack of metal layers. Particularly, the material of the solder islands is a solder material. The solder islands are spaced from each other in lateral direction, wherein a lateral direction is herein understood as a direction parallel to a main extension plane of the first element and/or parallel to the side of the first element on which the first solder structure is arranged. The vertical direction is a direction perpendicular to the main extension plane of the first element and/or the side on which the first solder structure is arranged, respectively. The expression “vertical” is in no way meant to be restrictive to directions parallel to the gravitational direction.

The solder islands are laterally spaced from each other by at least one trench, i.e. one or more trenches. The at least one trench may be formed as a grid having a plurality of meshes, wherein the solder islands are arranged in the meshes. Thus, the solder islands may each be laterally completely surrounded by the at least one trench.

The form of each solder island in plan view, i.e. when looking along the vertical direction, may be rectangular, round, triangular, pentagonal, hexagonal or a free-form. For example, in plan view, the solder islands each have a geometrical form with at least five corners.

The at least one trench may reach from the side of the first solder structure facing away from the first element until the first element or, alternatively, may open into the solder structure. Hence, the bottom side of the at least one trench may either be formed by the first element or by the first solder structure.

The width of the at least one trench, measured in lateral direction, is, for example, at least 1 μm or at least 2 μm or at least 5 μm. Additionally or alternatively, the width is at most 50 μm or at most 20 μm or at most 10 μm. The width of the trench defines the distance in lateral direction between two neighboring solder islands. The depth of the trench, measured in vertical direction, is, for example, at least 200 nm or at 500 nm and/or at most 1 μm or at most 800 nm.

Besides the first solder structure, the second solder structure may also comprise a plurality of solder islands being laterally spaced from each other and laterally separated from each other by at least one trench which extends from an outer surface of the second solder structure towards the second element. All features disclosed herein for the first solder structure, particularly concerning the solder islands and the at least one trench, are accordingly disclosed for the second solder structure.

Alternatively, the second solder structure may be a contiguous structure without trenches, i.e. a trench free structure.

According to at least one embodiment, at least one of the first and the second element comprises a semiconductor body. Moreover, at least one of the first and the second element may be or may comprise a carrier. For example, the first element comprises a semiconductor body and the second element is or comprises a carrier or vice versa. The at least one trench may reach to the semiconductor body or carrier, respectively, so that a bottom surface of the trench is formed by semiconductor material or the material of the carrier.

The semiconductor body may be an optoelectronic semiconductor body having at least one active layer configured to produce or absorb electromagnetic radiation. The active layer may be formed by a pn-junction or a single quantum well (SQW) or a multi-quantum well (MQW) structure. For example, the semiconductor body is based on a III-V-compound semiconductor material, like AlInGaN or AlInGaAs or AlInGaP. The semiconductor body may be grown epitaxially. The semiconductor body may comprise a plurality of semiconductor layers stacked above each other.

The carrier is, for example, electrically conducting. For example, the carrier comprises or consists of a semiconductor material, like doped Si or SiC, or comprises or consists of metal. The carrier may comprise or consist of a different semiconductor material than the semiconductor body. Alternatively, the carrier may also be formed of an electrically isolating material, like a ceramic.

According to at least one embodiment, the method comprises a step of producing a compound of the first element and the second element. Producing the compound includes a step of bringing the solder structures into contact, i.e. mechanical contact. Furthermore, producing the compound includes bonding the solder islands to the second solder structure. Thereby, solder joints are formed out of the solder islands which connect the first and the second element in a material-locking manner.

The bonding process is, in particular, a solder process. Hence, the solder islands are soldered to the second solder structure. Hereby, the solder material of the solder islands may partially or completely melt and subsequently solidifies again thereby forming the solder joints.

By way of example, each solder island is bonded to the second solder structure, i.e. enters into a material-locking connection with the second solder structure. In other words, each solder island may become a solder joint. The solder joints provide the material-locking connection between the first element and the second element.

According to at least one embodiment, a lateral movement of the solder material of the solder islands is at least limited, i.e. limited or even prevented, during bonding so that the solder material does not interrupt the at least one trench in vertical direction. As a consequence of this, after bonding, the resulting solder joints are laterally still spaced from each other and separated from each other by the at least one trench.

“Lateral movement” means, for example, lateral flow or lateral diffusion. Particularly, the solder material of the solder islands, when molten, is prevented from a lateral overflow over the at least one trench to the neighboring solder island. The merging of the solder materials of neighbouring solder islands is prevented. For example, the solder structures are configured such that the volume occupied by the at least one trench before and after bonding deviate from each other by at most 10%. Hence, the structure and volume of the at least one trench is largely maintained due to the prevention of the lateral overflow of the solder material.

In the case that the first and the second solder structure both comprise solder islands, both solder structures are, for example, brought into contact such that the solder islands and/or the trenches are aligned with each other in lateral direction. Alternatively, when the second solder structure is formed without a trench, e.g. by at least one contiguous metal layer which laterally extends over a plurality or all solder islands of the first solder structure, the solder islands of the first solder structure are brought into contact with the at least one contiguous metal layer.

In at least one embodiment of the method for producing at least one semiconductor device, the method comprises providing a first element with a first solder structure arranged thereon and providing a second element with a second solder structure arranged thereon. At least the first solder structure comprises a plurality of solder islands which are laterally spaced from each other and laterally separated from each other by at least one trench extending in a vertical direction from an outer surface of the first solder structure towards the first element. At least one of the first and the second element comprises a semiconductor body. The method further comprises producing a compound of the first and the second element which includes bringing the solder structures into contact and bonding the solder islands to the second solder structure so that solder joints are formed out of the solder islands which connect the first and the second element in a material-locking manner. During bonding, a lateral movement of the solder material of the solder islands is at least limited so that the solder material does not interrupt the at least one trench in vertical direction and so that the resulting solder joints are laterally spaced and separated from each other by the at least one trench.

Embodiments of the present invention are, inter alia, based on the recognition that surface-emitting optoelectronic devices need a wafer bonding process to implement light enhancing technologies. The purpose of the solder used during bonding is to ensure an electrical, thermal and mechanical connection between the semiconductor body and the carrier. In order to separate the resulting wafer compound into a plurality of semiconductor devices, one has to cut through the solder material. For this purpose, a laser or a mechanical cutting tool is normally used. However, when using these tools, one is usually limited to parallel, equidistant straight line cuts so that only rectangular semiconductor devices can be produced.

With the method described herein, the trenches define the geometrical shape of the finally produced semiconductor devices. Due to the prevention of the lateral overflow of the solder material, the trenches are maintained and, hence, in order to separate the compound into a plurality of semiconductor devices along the trenches, it is no longer necessary to cut through solder material. Rather, the non-interrupted trench provides a direct access from the first element to the second element which, in turn, enables, for example, a dry or wet chemistry based etch/singulation process (e.g. Bosch process). Consequently, one is not limited to rectangular shapes of the resulting semiconductor devices but several geometrical shapes can be produced.

Moreover, with the trenches not being filled with solder material, parallel device singulation is enabled which reduces the process time for device singulation, the main benefit being for smaller device dimensions. Parallel device singulation also enables trench width reduction due to reduced separation width between the devices (e.g. by reduced alignment tolerance buffer compared to laser based singulation). A reduction of destroyed or damaged material in the trench leads to increased active areas or higher quantity of devices. Consequently, costs are also reduced.

According to at least one embodiment, the compound of the first and the second element is separated into a plurality of semiconductor devices along the at least one trench. This is done after the bonding, particularly after solidification of the solder material.

According to at least one embodiment, separating is done without cutting through solder material or even without cutting through metal. This is enabled due to the maintenance of the at least one trench as explained above. For example, cutting is not used at all for separating the compound into a plurality of semiconductor devices. As a consequence of this, the resulting semiconductor devices may be free of any traces of a mechanical or laser induced material removal.

Separation may be done, for example, by means of a dry or wet etching process, like the Bosch process. For this purpose, a mask may be applied onto the first and/or the second element. For example, the mask is formed on the element comprising the semiconductor body. The mask may be produced with the help of lithography. In particular, the mask is aligned with the at least one trench such that, when applying the etchant, the etchant etches through the first and/or the second element in the regions of the at least one trench. For example, firstly, a first etchant is applied which etches through the first element and thereby exposes the trench(es). Then, a second etchant is applied, which reaches through the at least one trench to the second element and etches the second element in the region of the at least one trench. In this way, the compound is separated along the at least one trench.

In the region of the resulting solder joints, i.e. in the region which is laterally aligned with the solder joints, the first and/or second element may not be etched, e.g. may be protected from the etchant(s) by the mask.

According to at least one embodiment, the solder structures comprise a first and a second metal. The first and the second metal are different from each other. The metals may be already mixed to an alloy when providing the first and the second element or may first be separated and, only during forming the compound, may mix to an alloy. For example, the alloy is already present before the bonding. At least a portion of the alloy may melt during the bonding.

Before producing the compound, each of the two solder structures may either comprise only one of the first and the second metal or both metals. Alternatively, one of the first and the second solder structure may comprise the first and the second metal and the other one of the solder structures may comprise only one of the first and the second metal, e.g. the first metal.

According to at least one embodiment, a major part of the solder joints is formed of the alloy comprising the first and the second metal. In the solder joints, the alloy has a ratio between the concentration of the first and the concentration of the second metal being a target ratio. “Concentration” hereby refers to the atomic concentration.

For example, the target ratio between the concentrations is a non-eutectic ratio, i.e. the target ratio is away from the eutectic ratio(s) at which the alloy melts and solidifies at a single temperature. The target ratio may deviate from an eutectic ratio by at least 0.1 or at least 0.5.

According to at least one embodiment, during production of the compound, e.g. before and/or during bonding, the ratio between the concentration of the first and the concentration of the second metal in the alloy changes so that the alloy passes at least one intermetallic phase transition until the target ratio is reached. Preferably, the alloy passes at least two intermetallic phase transitions or at least three intermetallic phase transitions before reaching the target ratio. For example, the ratio of the concentrations thereby changes from lying above the eutectic ratio to lying below the eutectic ratio or vice versa.

By choosing the solder structure and/or the conditions during bonding such that intermetallic phase transitions have to be passed in order to reach the target ratio, the viscosity of the alloy is kept large because each intermetallic phase transition draws enthalpy from the system which limits the amount of liquid present during the bonding. In this way, a lateral movement of the solder material can be limited or even prevented.

Herein, an intermetallic phase transition is defined as a phase transition in which the alloy stays at least partially solid, for example completely solid. That is, in an intermetallic phase transition, the alloy does not become completely liquid.

In at least one embodiment of the method for producing at least one semiconductor device, the method comprises providing a first element with a first solder structure arranged thereon and providing a second element with a second solder structure arranged thereon. At least one of the first and the second element comprises a semiconductor body. The method further comprises producing a compound of the first element and the second element which includes bringing the solder structures into contact and bonding the first solder structure to the second solder structure so that at least one solder joint is formed which connects the first and the second element in a material-locking manner. The solder structures comprise a first and a second metal. A major part of the at least one solder joint is formed of an alloy comprising the first and the second metal, wherein, in the at least one solder joint, the alloy has a ratio between the concentration of the first and the concentration of the second metal being a target ratio. During production of the compound, the ratio between the concentration of the first and the concentration of the second metal in the alloy changes such that the alloy passes at least one intermetallic phase transition until the target ratio is reached.

According to at least one embodiment, one of the first solder structure and the second solder structure comprises a layer stack with a layer of the first metal and a layer of the second metal. For example, each solder island comprises such a layer stack or consists thereof. The layers of the first and the second metal may be in direct contact or may be separated from each other, e.g. by a temporary barrier layer.

According to at least one embodiment, the other one of the first and the second solder structure comprises a further layer of the first metal. The other one of the first and the second solder structure may also comprise a layer stack with a further layer of the first metal and a further layer of the second metal.

According to at least one embodiment, at least one of the first and the second solder structure comprises a solder barrier layer. The solder barrier layer comprises or consists of, for example, at least one third metal which is different from the first and the second metal. For example, the first and the second solder structure both comprise a solder barrier layer.

According to at least one embodiment, for the production of the compound, the layer stack is heated to a first temperature so that the first metal and the second metal of the two layers of the layer stack mix to form the alloy. The first temperature is, for example, chosen such that the alloy does not yet melt. Heating to the first temperature is, for example, done before the solder structures are brought into contact.

According to at least one embodiment, after heating to the first temperature and/or after bringing the first and the second solder structures in contact, the alloy is heated to a second temperature which is greater than the first temperature. For example, the second temperature is at least 50° C. above the first temperature.

According to at least one embodiment, when the first and the second solder structure are in contact and when the alloy is heated up to the second temperature, the first metal of the further layer mixes with the alloy, thereby increasing the concentration of the first metal. Furthermore, the alloy at least partially melts. Thus, the second temperature and/or the concentration ratio in the alloy are such that the alloy melts at least partially.

According to at least one embodiment, the solder barrier layer is chosen such that it does not melt at the second temperature and such that the second metal of the molten alloy diffuses into the solder barrier layer so that the concentration of the first metal in the molten alloy further increases until the alloy isothermally solidifies at the second temperature and reaches the target ratio.

According to at least one embodiment, the first metal is Au and the second metal is Sn.

According to at least one embodiment, the solder barrier layer comprises or consists of at least one of: Ni, Pt, Pd.

According to at least one embodiment, the temporary solder barrier layer comprises or consists of Ti.

According to at least one embodiment, the first temperature is between 100° C. and 280° C. inclusive. For example, the first temperature is between 150° C. and 250° C. inclusive.

According to at least one embodiment, the second temperature is between 300° C. and 500° C. inclusive, for example between 300° C. and 380° C. inclusive.

According to at least one embodiment, the layers of the first metal each have a thickness between 10 nm and 1.5 μm inclusive. For example, the layers of the first metal each have a thickness between 100 nm and 500 nm inclusive. By way of example, one layer of the first metal, e.g. that of the layer stack, has a thickness between 100 nm and 200 nm inclusive, and the other layer of the first metal has a thickness between 250 nm and 350 nm inclusive

According to a further embodiment, the layer of the second metal has a thickness between 100 nm and 1.5 μm inclusive, for example between 200 nm and 400 nm inclusive.

According to at least one embodiment, the solder barrier layer has a thickness between 1 nm and 10 μm inclusive, e.g. between 50 nm and 200 nm inclusive.

According to at least one embodiment, the temporary solder barrier layer has a thickness between 1 nm and 20 nm inclusive.

According to at least one embodiment, the ratio of the concentrations of the first and the second metal in the alloy before bringing the first and the second solder structure into contact is between 1 and 50 inclusive, for example between 1.2 and 9 inclusive.

According to at least one embodiment, the melting temperature of the solder barrier layer is greater than the second temperature, e.g. at least 50° C. or at least 100° C. greater than the second temperature.

According to at least one embodiment, the layers of the first metal are outermost layers of the solder structures which are exposed before bringing the first and the second solder structure into contact.

According to at least one embodiment, the at least one trench is filled with gas, for example air or a processing gas, during bonding. The solder material and the bonding conditions are then chosen such that a lateral movement is at least limited, e.g. using the process and the solder structures mentioned above. Also after bonding, i.e. after the solder joints have been formed and before separating the compound, the at least one trench can be filled with the gas.

According to at least one embodiment, the at least one trench is filled with a solid filling material during bonding. The filling material may be an electrically isolating material, for example SiO₂. Due to the fact that the at least one trench is filled with the filling material, the lateral movement of the solder material can be prevented or at least limited, because the filling material blocks the lateral movement. In this case, the choice of the solder material and or the bonding conditions are less constrained.

According to at least one embodiment, before bonding, the semiconductor body is grown on a growth substrate of the corresponding element. For example, the growth substrate is sapphire. The semiconductor body may be arranged between the growth substrate and the solder structure of the corresponding element.

According to at least one embodiment, after producing the compound, the growth substrate is at least partially removed from the semiconductor body. For example, the growth substrate is completely removed from the semiconductor body.

With the semiconductor body being an optoelectronic semiconductor body, the removal of the growth substrate enables so-called thin-film chips or surface-emitting chips to be produced, respectively.

Next, the semiconductor device is specified. The semiconductor device may be produced with the method according to any one of the embodiments described herein. Therefore, all features disclosed for the method are also disclosed for the semiconductor device and vice versa.

According to at least one embodiment, the semiconductor device comprises a semiconductor body and a carrier. The semiconductor body is connected to the carrier by means of at least one solder joint, i.e. only one or more solder joints. For example, by means of the solder joint, the semiconductor body is mechanically and eventually electrically and/or thermally connected to the carrier. The semiconductor body is, in particular, an epitaxially grown semiconductor body, for example an epitaxially grown semiconductor layer sequence.

According to at least one embodiment, the semiconductor device is a thin-film semiconductor device in which the growth substrate of the semiconductor body is at least largely removed, for example completely removed.

According to at least one embodiment, at least one lateral surface, particularly all lateral surfaces, of the at least one solder joint is free of traces of a cutting process, in particular free of traces of a mechanical or laser induced cutting process. A lateral surface of the at least one solder joint runs obliquely or perpendicularly to a lateral direction. For the semiconductor device, a lateral direction is herein defined, for example, as a direction parallel to a main extension plane of the carrier and/or the semiconductor body. A lateral surface is, in particular, a surface that is oblique or perpendicular to this main extension plane. Lateral surfaces of the semiconductor body and/or the carrier may comprise traces of a material removal, e.g. of an etching process.

The solder joint may cover a major part of the side of the semiconductor body facing towards the carrier. For example, the solder joint covers at least 80% or at least 90% or 100% of that side of the semiconductor body. In other words, the space between the carrier and the semiconductor body is, to a major part, filled with the solder joint, e.g. to at least 80% or to at least 90% or completely.

In at least one embodiment, the semiconductor device comprises a semiconductor body and a carrier. The semiconductor body is connected to the carrier by means of at least one solder joint. The semiconductor device is a thin-film device in which a growth substrate of the semiconductor body is at least largely removed. At least one lateral surface of the at least one solder joint is free of traces of a cutting process.

The semiconductor device produced with the method is also referred to as semiconductor chip. The semiconductor device may be used in automotive applications or illumination applications.

The at least one solder joint may also be used for an electrical connection of the semiconductor body via the carrier. For example, a first contact area of the semiconductor device is arranged on a backside of the carrier and faces away from the semiconductor body. A second contact area, e.g. of an opposite polarity to the first contact area, may be provided on a front side of the carrier and may face in the opposite direction to the first contact area. The contact areas are configured for an external electrical connection of the semiconductor device.

All features disclosed herein for one lateral surface of the solder joint are correspondingly disclosed for all other lateral surfaces of the solder joint. Likewise, all features disclosed herein for one solder joint are correspondingly disclosed for all solder joints of the semiconductor device.

According to at least one embodiment, the lateral surface of the at least one solder joint is exposed. This means that the solder material of the solder joint is exposed at the lateral surface.

According to at least one embodiment, the lateral surface of the solder joint is concavely curved.

According to at least one embodiment, the lateral surface of the solder joint is at least partially covered with an electrically isolating, solid material, e.g. with SiO₂. The material is, for example, the filling material with which the at least one trench was filled during production of the compound. A lateral surface of the solid, electrically isolating material facing away from the solder joint may comprise traces of a material removal process, like traces of etching.

According to at least one embodiment, the lateral surface of the solder joint is retracted at least in places with respect to a lateral surface of the semiconductor body and/or the carrier, the surfaces of which face in the same direction as the lateral surface of the solder joint. For example, the retraction is at least 0.5 μm or at least 1 μm and/or at most 10 μm.

The lateral surfaces of the semiconductor body and the carrier facing in the same direction may terminate flush with each other, i.e. terminate at the same height with respect to the lateral direction in which they face. For example, the lateral dimensions of the semiconductor body and the carrier are equal within the limits of manufacturing tolerances, e.g. within 5%.

According to at least one embodiment, the semiconductor device is an optoelectronic device for emitting or absorbing electromagnetic radiation. Particularly, the semiconductor device is a LED chip. The semiconductor device may be configured for emitting UV-radiation or IR-radiation and/or visible light.

According to at least one embodiment, in plan view of a top side of the semiconductor device, the geometrical form of the semiconductor device is different from a rectangle. The top side is, for example, the main side of the semiconductor body, i.e. a side with the largest area. The top side may be a main radiation side of the optoelectronic semiconductor device. The top side faces away from the carrier, for example.

For example, in plan view, the geometrical form of the semiconductor device is that of an ellipse, circle, triangle, pentagon, hexagon or a geometrical body with more than six corners. The geometrical form may also be a free-form.

With the geometrical form being different from a rectangle, particularly being that of a circle or an ellipse, the semiconductor device is better suited to be connected to an optical element, like a lens, which usually has a round shape.

According to at least one embodiment, the at least one solder joint comprises an alloy having a first and a second metal. The solder joint may be largely formed by the alloy, e.g. to at least 80% or at least 90% or completely. The concentration of the first and the second metal in the alloy is, for example, at least 10 at-% in each case. For example, the concentration of the first metal in the solder joint is at least 50 at-% or at least 70 at-%. The concentration of the second metal in the solder joint is, e.g., at least 10 at-% or at least 12 at-%.

According to at least one embodiment, the concentrations of the first and the second metal in the alloy are in a non-eutectic ratio. For example, the concentration of the first metal is at least 5 at-% or at least 10 at-% away from or above the eutectic ratio.

According to at least one embodiment, a solder barrier layer is arranged between the solder joint and the semiconductor body and/or a solder barrier layer is arranged between the solder joint and the carrier.

According to at least one embodiment the solder barrier layers each comprise at least one third metal which is different from the first and the second metal.

According to at least one embodiment, the concentration of the third metal in the alloy is at most 10 at-% or at most 5 at-%. The concentration of the first metal in the solder barrier layers is at most 15 at-% or at most 10 at-% or at most 7 at-%. The concentration of the second metal in the solder barrier layers is at least at-10% and/or at most 50 at-%. The concentration of the third metal in the solder barrier layers is, for example, at least 50 at-% or at least 70 at-%

In at least one embodiment, the semiconductor device comprises a semiconductor body and a carrier. The semiconductor body is connected to the carrier by means of at least one solder joint. The solder joint comprises an alloy with a first and a second metal with a concentration of the first and the second metal in the alloy being in each case at least 10 at-%. The concentrations of the first and the second metal in the alloy are in a non-eutectic ratio. A solder barrier layer is arranged between the solder joint and the semiconductor body and a solder barrier layer is arranged between the solder joint and the carrier. The solder barrier layers each comprise at least one third metal. The concentration of the third metal in the alloy is at most 10 at-%, the concentration of the first metal in the solder barrier layers is at most 15 at-% and the concentration of the second metal in the solder barrier layers is at least 10 at-%.

According to at least one embodiment, the first metal is Au and the second metal is Sn. Thus, the alloy is an AuSn alloy. For example, the alloy is in the ζ-phase or ζ′-phase.

According to at least one embodiment, the third metal is at least one of Ni, Pt, Pd. The solder barrier layers may comprise several or all of these metals.

According to at least one embodiment, the solder joint has a thickness between 100 nm and 5 μm inclusive, for example between 400 nm and 1 μm inclusive or between 600 nm and 900 nm inclusive.

According to at least one embodiment, the solder barrier layers each have a thickness between 1 nm and 10 μm inclusive, e.g. between 50 nm and 200 nm inclusive.

The solder barrier layers may adjoin the solder joint.

### BRIEF DESCRIPTION OF THE DRAWINGS

Hereinafter, the method for producing at least one semiconductor device and the semiconductor device will be explained in more detail with reference to the drawings on the basis of exemplary embodiments. The accompanying figures are included to provide a further understanding. In the figures, elements of the same structure and/or functionality may be referenced by the same reference signs. It is to be understood that the embodiments shown in the figures are illustrative representations and are not necessarily drawn to scale. In so far as elements or components correspond to one another in terms of their function in different figures, the description thereof is not repeated for each of the following figures. For the sake of clarity, elements might not appear with corresponding reference symbols in all figures.

FIGS. 1 to 4 and 6 to 7 show different positions in a first exemplary embodiment of the method for producing at least one semiconductor device;

FIG. 5 shows the phase diagram of AuSn;

FIG. 8 shows a photograph taken during the method;

FIG. 9 shows a cross-sectional view of a first exemplary embodiment of the semiconductor device;

FIG. 10 shows exemplary embodiments of the semiconductor device in the plan view on the top side;

FIGS. 11 to 14 show different positions in a second exemplary embodiment of the method; and

FIG. 15 shows a further exemplary embodiment of the semiconductor device.

### DETAILED DESCRIPTION OF ILLUSTRATIVE EMBODIMENTS

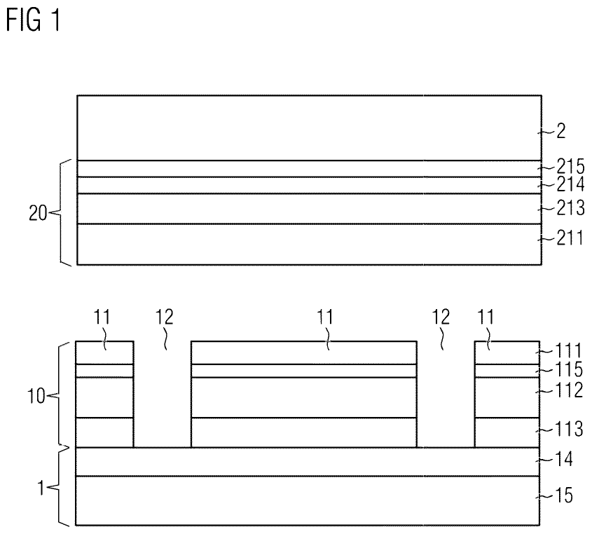

In the position of FIG. 1, a first element 1 and a second element 2 are provided. The second element 2 is a carrier, e.g. of Si. The first element 1 comprises a semiconductor body 14 and a growth substrate 15 for the semiconductor body 14. The growth substrate 15 is, e.g., sapphire. The semiconductor body 14 is, for example, a semiconductor layer sequence based on AlInGaN and is epitaxially grown on the growth substrate 15. The semiconductor body 14 is intended to produce electromagnetic radiation during normal operation.

On one side of the first element 1, a first solder structure 10 comprising a plurality of solder islands 11 is arranged. Each solder island 11 comprises a stack of metal layers. The stacks each comprise four layers 113, 112, 115, 111. A solder barrier layer 113 is closest to the semiconductor body 14. The solder barrier layer 113 comprises or consists of at least one of: Ni, Pt, Pd. Layer 113 has a thickness of, for example, 150 nm. On top of the solder barrier layer 113, a layer 112 of a Sn is applied. The thickness of layer 112 is, for example, 300 nm. The layer 112 may be in direct contact to the layer 113. On top of layer 112, a temporary solder barrier layer 115 of Ti with a thickness of 5 nm is applied. The layer 115 may be in direct contact to layer 112. A layer 111 of Au with a thickness of, for example, 150 nm is applied on the layer 115. The layer 111 may be applied directly to the layer 115.

The solder islands 11 are laterally spaced from each other and separated from each other by at least one trench 12 which extends from the side facing away from the first element 1 in a vertical direction towards the first element 1 without reaching into the first element 1. The at least one trench 12 has, for example, a width of 10 μm.

On one side of the second element 2, a second contact structure 20 is applied comprising a layer stack of different metal layers 211, 213, 214, 215. The layer stack comprises, closest to the second element 2, a functional layer 215, for example of Pt and/or Au. The functional layer 215 may be configured to provide adhesion, a diffusion barrier, stress compensation and/or electric contact. The thickness of the functional layer 215 is, e.g., 5 nm. A layer 214 of Ti having a thickness of about 5 nm is arranged on the functional layer 215 and is, for example, in direct contact with the functional layer 215. A solder barrier layer 213 comprising or consisting of at least one of Ni, Pd, Pt and having a thickness of, for example, 100 nm is applied onto layer 214 and is, for instance, in direct contact with layer 214. Finally, a layer 211 of Au is applied directly on the layer 213, wherein layer 211 has, for example, a thickness of 300 nm.

The layers 111 and 211 of Au form outermost layers of the solder structures 10, 20 and are exposed in FIG. 1.

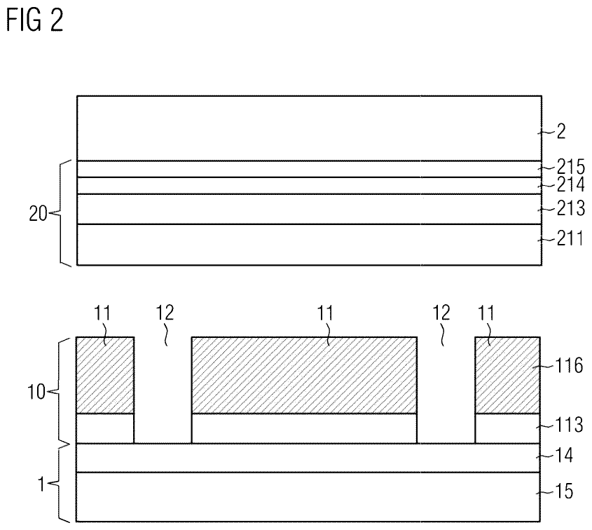

In the position of FIG. 2, the first solder structure 10 is heated up to a first temperature T1. In this step, the solder structures 10 and 20 are still spaced from each other. The first temperature T1 is, for example, between 100° C. and 280° C. Due to the increased temperature, the temporary solder barrier layer 115 is broken through and the metals of the layers 111 and 112, namely Au and Sn, start to mix and form an AuSn alloy 116. The temperature T1 is thereby chosen such that the formed alloy 116 does not yet melt.

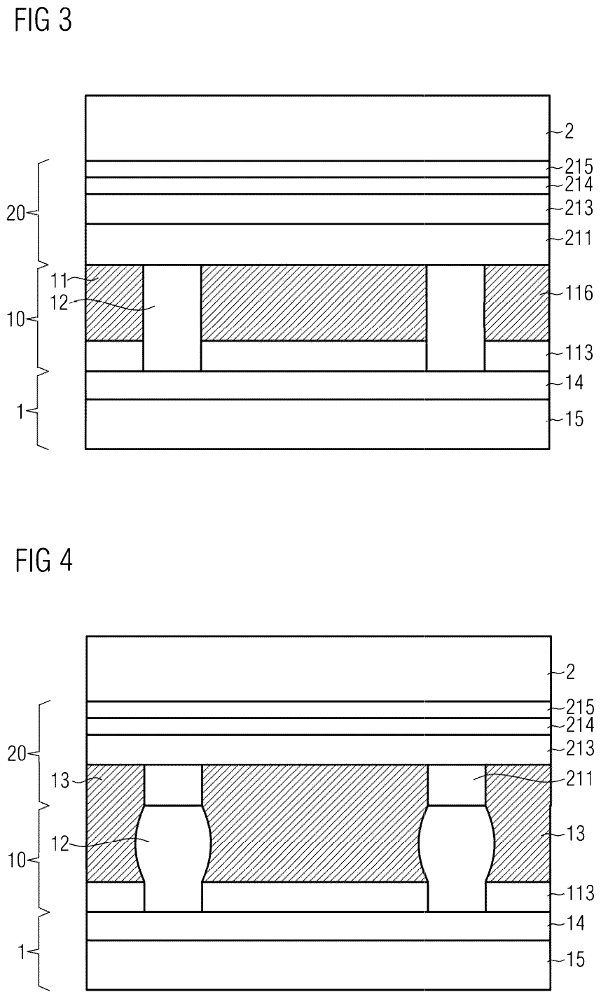

In FIG. 3, a position is shown, in which the first solder structure 10 and the second solder structure 20 are brought into contact so that the layer 211 of Au adjoins the alloy 116. The temperature is now further increased to a second temperature T2, for example 340° C. The Au of layer 211 starts to mix with the alloy 116 so that the concentration of Au is increased in the alloy 116. The second temperature T2 and the composition of the alloy 116 is thereby chosen such that the alloy 116 at least partially melts. At the same time, however, Sn diffuses from the alloy 116 into the barrier layers 113, 213 so that the concentration of Au in the alloy 116 further increases such that the melting temperature of the alloy 116 increases above the second temperature T2. Due to this, the alloy 116 solidifies at the still set second temperature T2, i.e. the alloy 116 solidifies isothermally. The result is shown in FIG. 4.

Due to the described process, the alloy 116 only melts for a short time so that a lateral flow of the molten alloy 116 is limited. Particularly, the molten alloy 116 does not flow into the at least one trench 12. Consequently, the trench 12 is not interrupted in vertical direction by solidified solder material. During soldering, solder islands 11 have become solder joints 13 which provide a material-locking connection between the first 1 and the second 2 element and which are still laterally separated and spaced from each other by the at least one trench 12.

As becomes apparent from FIG. 4, the melting of the alloy 116 has slightly changed the shape of the solder islands 11, namely such that lateral surfaces of the resulting solder joints 13 are concavely curved.

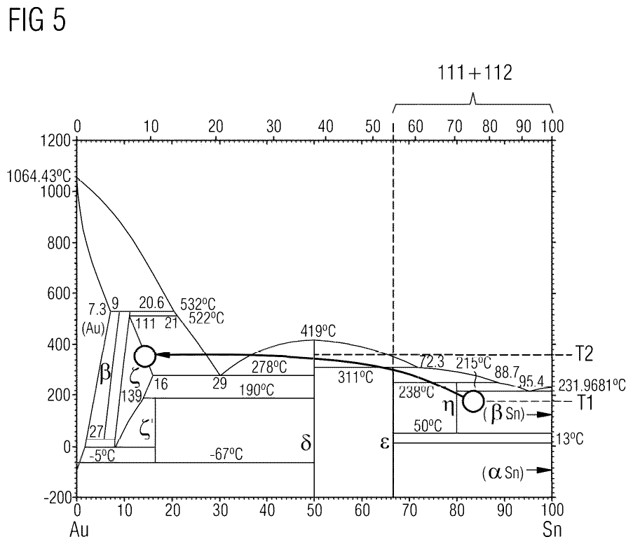

FIG. 5 shows the phase diagram of the AuSn alloy or system, respectively. The x-axis indicates the at-% of Au and Sn, wherein the Au concentration is 100 at-% on the left end of the diagram and the Sn concentration is 100 at-% on the right end. On the y-axis, the temperature is indicated.

The right circle in FIG. 5 marks the position in the phase diagram which is reached, when the first temperature T1 is set and where the alloy 116 of Au and Sn has formed out of the layers 111 and 112 (see FIG. 3). The left circle shows the position in the phase diagram after isothermal solidification of the alloy 116, hence when the solder joints 13 are already formed. At this left point, the temperature is still the second temperature T2.

As can be seen in FIG. 5, the alloy 116 of the final solder joints (left circle) is in the ζ-phase, away from the eutectic points. The arrow between the left and the right circle indicates the path of the alloy 116 in the phase diagram. The increase from the first Ti to the second T2 temperature T2 together with the increase of the Au has as a consequence that the alloy 116 makes several intermetallic phase transitions, namely, inter alia, from n-phase to ¿-phase and from ε-phase to δ-phase. Each of these intermetallic phase transitions draws enthalpy from the AuSn system limiting the amount of liquid in the alloy 116. Only for a short time, a liquid phase appears, but due to the further increase of the Au concentration, isothermal solidification happens shortly after that and the target concentration of Au and Sn is reached with the concentration of Au being approximately 85 at-% and the concentration of Sn being approximately 15 at-%.

In reality, the alloy 116 of the solder joints 13 may also comprise a certain amount of the metal of the solder barrier layers 113, 213, for example about 10 at-%. Due the absorption of Sn by the solder barrier layers 113, 213, these layers comprise a considerable amount of Sn after the bonding. Moreover, a certain amount of Au also diffuses into the solder barrier layers 113, 213. For example, after the bonding, the solder barrier layers 113, 213 each comprise at most 15 at-% Au and at least 10 at-% Sn.

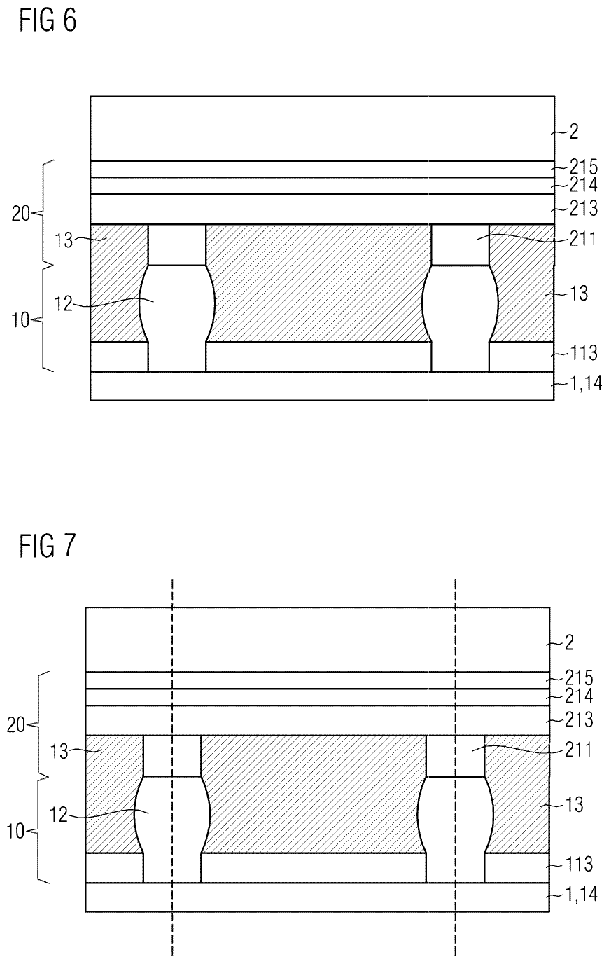

In the position of FIG. 6, the growth substrate 15 of the semiconductor body 14 is removed, e.g. by etching or laser ablation.

In the position of FIG. 7, the compound of the first element 1 and the second element 2 is separated into a plurality of semiconductor devices. Separation is done along the at least one trench 12 (indicated by the dashed separation lines). For example, a Bosch etching process is applied in which an etchant etches through the carrier 2 and the semiconductor body 14 in the region of the at least one trench 12. The separation is, for example, done without a cutting process, like a mechanical cutting process or a laser cutting process. This is enabled because the at least one trench 12 is not interrupted in vertical direction by the solder material so that the etchant can reach the carrier 2 and the semiconductor body 14 through the at least one trench 12.

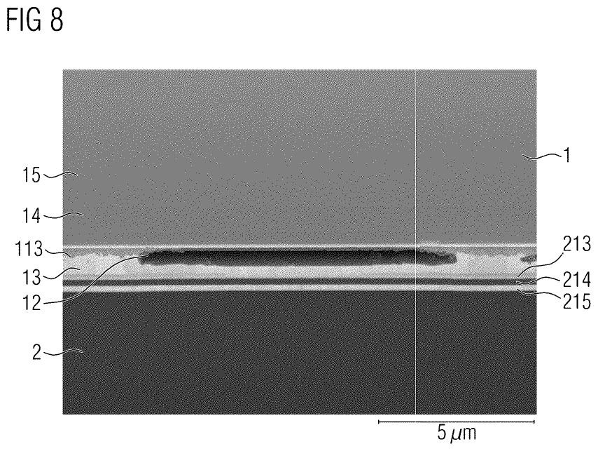

In FIG. 8, a photograph of an actually produced compound of a first element 1 and a second element 2 is shown. As can be seen here, the trench 12 is indeed maintained and not filled with solder material. The lateral surfaces of the solder joints 13 have a concave curvature which is due to the short phase of molten alloy

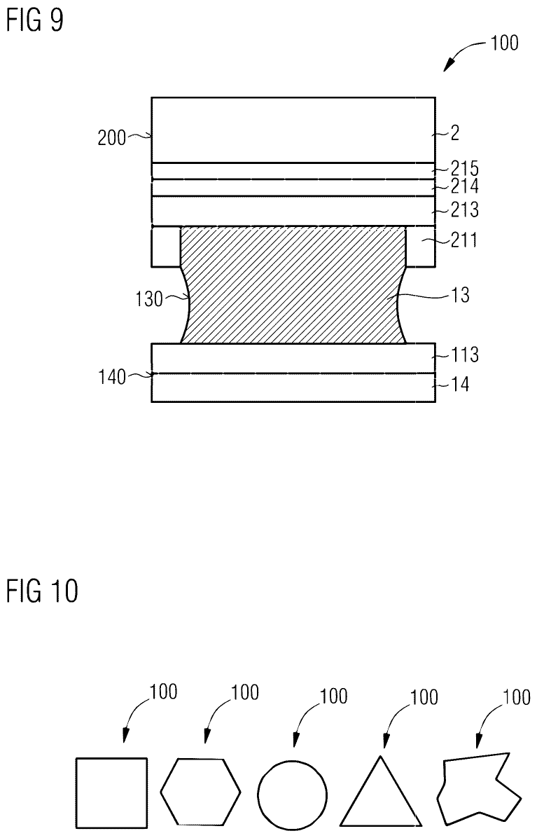

FIG. 9 shows an exemplary embodiment of a semiconductor device 100 which is produced with the method described before. The solder joint 13 connects the carrier 2 and the semiconductor body 14 in a material-locking manner. The exposed lateral surface 130 of the solder joint 13 is concavely curved and is free of traces of a cutting process. Compared to the lateral surfaces 200 and 140 of the carrier 2 and the semiconductor body 14, the lateral surfaces 130 of the solder joints 13 are retracted in lateral direction. The lateral surfaces 200, 140 have traces of material removal due to the separation process, e.g. traces of an etching process. The solder joint 14 is, furthermore, laterally completely surrounded by a remnant of the layer 211, which still consists, e.g., of Au.

The semiconductor device 100 of FIG. 9 is, for example, an optoelectronic semiconductor device for emitting electromagnetic radiation, like UV-radiation, visible light or IR-radiation. Particularly, it is a so-called thin-film chip since the growth substrate of the semiconductor body 14 has been removed.

FIG. 10 shows different exemplary embodiments of the semiconductor device 100 in plan view on the top side, which is for example formed by the semiconductor body 14. As can be seen, different geometrical forms are realized. The geometrical form can be predefined by the form of the at least one trench 12 or the solder islands 11, respectively. Since the at least one trench 12 is not filled with the solder material during the soldering/bonding, a cutting process is not necessary and, consequently, one is not limited to rectangular shapes.

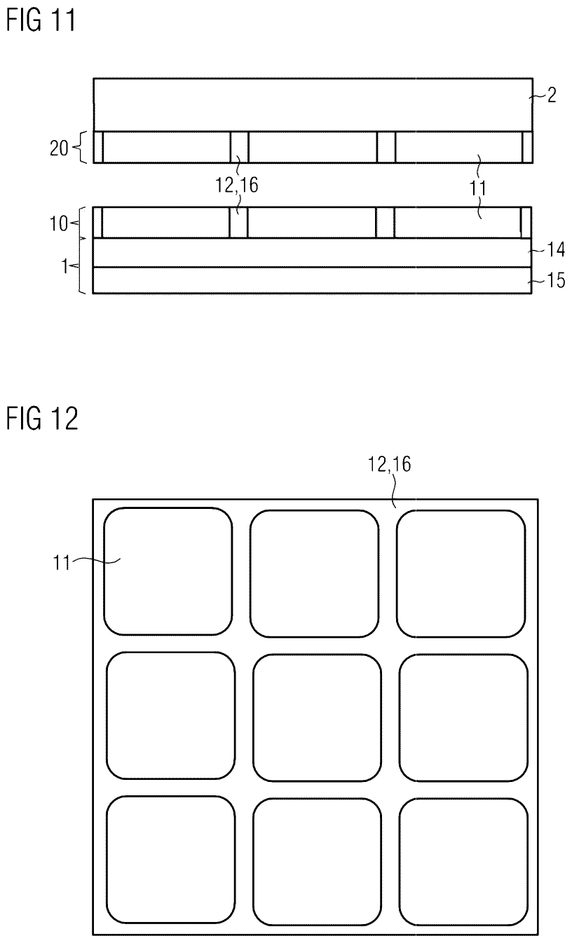

FIG. 11 shows a position in a second exemplary embodiment of the method. In this case, both the first solder structure 10 and the second solder structure 20 comprise solder islands 11 which are laterally separated and spaced from each other by at least one trench 12. The trenches 12 are filled with a solid, electrically isolating filling material 16. The material 16 is, for example, SiO₂.

FIG. 12 shows a plan view on one of these solder structures 10, 20. As can be seen, the trench 12 is formed as a grid with a plurality of meshes and each of the meshes is assigned a solder island 11.

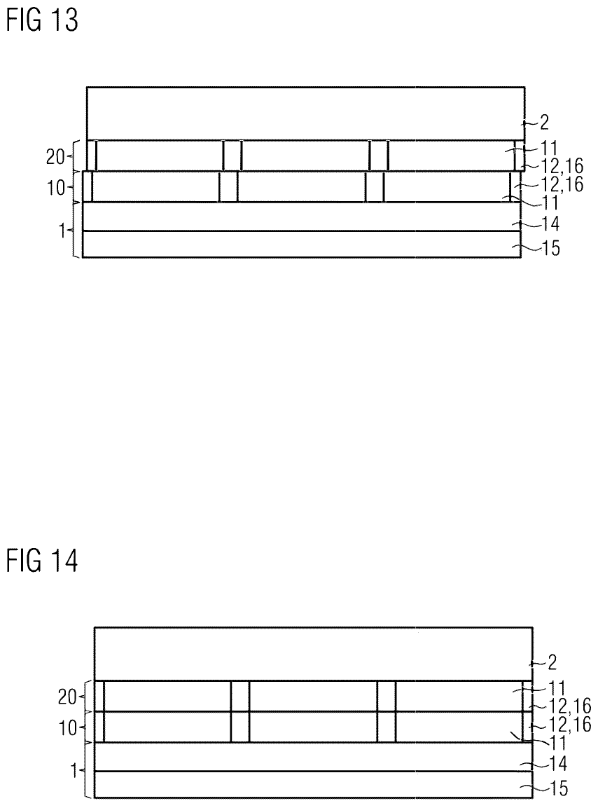

In FIG. 13, a position is shown, in which the solder structures 10, 20 are brought into contact. A perfect alignment between the trenches 12 and/or the solder islands 11 of the two solder structures 10, 20 is difficult so that a small misalignment appears.

In FIG. 14, a position is shown in which a bonding step, namely soldering step, is performed. In this step, at least a part of the solder islands 11 melts. Due to the minimization of the surface energy of the molten solder material, a self alignment between the element 2 and the element 1 happens so that the alignment between the trenches 12 and the solder islands 11 is automatically improved. Moreover, due to the trenches 12 being filled with the filling material 16, a lateral overflow of the molten solder material is prevented so that the trenches 12 are maintained.

The connection between the first 1 and the second 2 element is only obtained here by the soldering, for example. Direct bonding between the filling materials 16 of the trenches 12 may be dismissed since this is not feasible due to high strain of the semiconductor body 14.

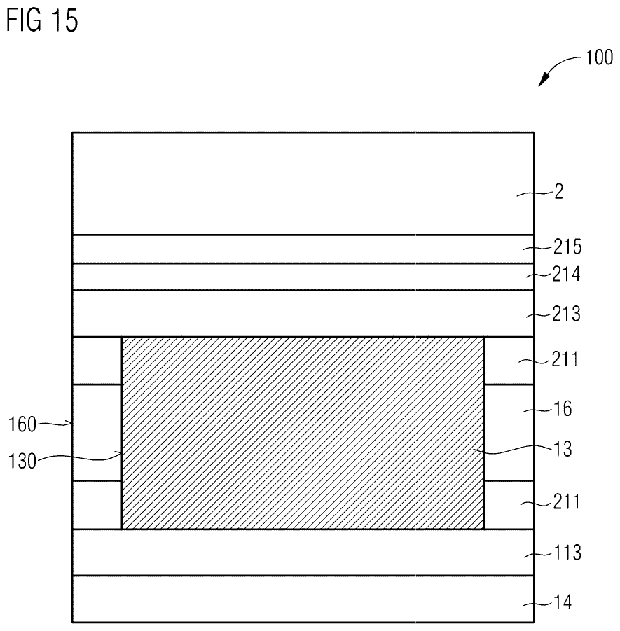

FIG. 15 shows an exemplary embodiment of the semiconductor device 100 as it results from the method described in connection with FIGS. 11 to 14 after a separation process along the trench 12. The molten material of the solder islands 11 has solidified and solder joints 13 have formed. In the device of FIG. 15, the lateral surfaces 130 of the solder joints 13 are still covered with the filling material 16 of the trenches 12. Lateral surfaces 160 of the material 16 covering the solder joints 13 are exposed and show, for example, traces of a material removal process, like etching traces.

The invention is not limited by the description based on the exemplary embodiments. Rather, the invention comprises any new feature as well as any combination of features, which in particular includes any combination of features in the patent claims, even if these features or this combination itself is not explicitly stated in the patent claims or embodiments.

1.-19. (canceled)

20. A method for producing at least one semiconductor device, the method comprising:
providing a first element with a first solder structure arranged thereon and providing a second element with a second solder structure arranged thereon,
wherein at least the first solder structure comprises a plurality of solder islands which are laterally spaced from each other and separated by at least one trench extending in a vertical direction from an outer surface of the first solder structure towards the first element, and wherein at least one of the first and the second element comprises a semiconductor body; and
producing a compound of the first and the second element by:
bringing the solder structures into contact; and
bonding the solder islands to the second solder structure so that solder joints are formed out of the solder islands which connect the first and the second element in a material-locking manner,
wherein a lateral movement of a solder material of the solder islands is at least limited during bonding so that the solder material does not interrupt the at least one trench in vertical direction and so that the resulting solder joints are laterally spaced and separated from each other by the at least one trench,
wherein the solder structures comprise a first metal and a second metal,
wherein a major part of the solder joints is formed of an alloy comprising the first metal and the second metal,
wherein, in the solder joints, the alloy has a ratio between a concentration of the first metal and a concentration of the second metal being a target ratio, and
wherein, during production of the compound, the ratio between the concentration of the first metal and the concentration of the second metal in the alloy changes such that the alloy passes at least two intermetallic phase transitions until the target ratio is reached.

21. The method according to claim 20,
wherein, after the bonding, the compound of the first element and the second element is separated into a plurality of semiconductor devices along the at least one trench, and
wherein separating is done without cutting through the solder material.

22. The method according to claim 20,
wherein one of the first solder structure and the second solder structure comprises a layer stack with a layer of the first metal and a layer of the second metal,
wherein the other one of the first solder structure and the second solder structure comprises a further layer of the first metal,
wherein at least one of the first solder structure and the second solder structure comprises a solder barrier layer, and
wherein the method further comprises:
before bringing the first solder structure and the second solder structure into contact, heating the layer stack to a first temperature so that the first metal and the second metal of two layers of the layer stack mix to form the alloy, and
after heating to the first temperature and/or after bringing the first solder structure and the second solder structure into contact, heating the alloy to a second temperature being greater than the first temperature so that the first metal of the further layer mixes with the alloy thereby increasing the concentration of the first metal in the alloy and so that the alloy at least partially melts,
wherein the solder barrier layer is chosen such that it does not melt at the second temperature and such that the second metal of the molten alloy diffuses into an absorption layer so that the concentration of the first metal in the molten alloy further increases until the alloy isothermally solidifies at the second temperature and reaches the target ratio.

23. The method according to claim 22,
wherein the first metal is Au,
wherein the second metal is Sn,
wherein the solder barrier layer comprises at least one of Ni, Pt, or Pd,
wherein the first temperature is between 100° C. and 280° C., inclusive,
wherein the second temperature is between 300° C. and 500° C., inclusive,
wherein the layers of the first metal each have a thickness between 10 nm and 1.5 μm, inclusive,
wherein the layer of the second metal has a thickness between 100 nm and 1.5 μm, inclusive, and
wherein the solder barrier layer has a thickness between 1 nm and 10 μm, inclusive.

24. The method according to claim 22, wherein the layers of the first metal are outermost layers of the solder structures, which are exposed before bringing the first solder structure and the second solder structure into contact.

25. The method according to claim 20, wherein, during bonding, the at least one trench is filled with gas.

26. The method according to claim 20, wherein, during bonding, the at least one trench is filled with a solid filling material.

27. The method according to claim 20,
wherein, before bonding, the semiconductor body is grown on a growth substrate of the corresponding element, and
wherein, after producing the compound, the growth substrate is at least partially removed from the semiconductor body.

28. A method for producing at least one semiconductor device, the method comprising:
providing a first element with a first solder structure arranged thereon and providing a second element with a second solder structure arranged thereon, wherein at least one of the first element or the second element comprises a semiconductor body; and
producing a compound of the first element and the second element by:
bringing the solder structures into contact; and
bonding the first solder structure to the second solder structure so that at least one solder joint is formed which connects the first element and the second element in a material-locking manner,
wherein the solder structures comprise a first metal and a second metal,
wherein a major part of the at least one solder joint is formed of an alloy comprising the first metal and the second metal,
wherein, in the at least one solder joint, the alloy has a ratio between a concentration of the first metal and a concentration of the second metal being a target ratio, and
wherein, during production of the compound, the ratio between the concentration of the first metal and the concentration of the second metal in the alloy changes such that the alloy passes at least two intermetallic phase transition until the target ratio is reached.

29. The method according to claim 28,
wherein one of the first solder structure and the second solder structure comprises a layer stack with a layer of the first metal and a layer of the second metal,
wherein the other one of the first solder structure and the second solder structure comprises a further layer of the first metal,
wherein at least one of the first solder structure and the second solder structure comprises a solder barrier layer,
wherein the method further comprises:
before bringing the first and the second solder structures into contact, heating the layer stack to a first temperature so that the first metal and the second metal of two layers of the layer stack mix to form the alloy,
after heating to the first temperature and/or after bringing the first solder structure and the second solder structures into contact, heating the alloy to a second temperature being greater than the first temperature so that the first metal of the further layer mixes with the alloy thereby increasing the concentration of the first metal in the alloy and so that the alloy at least partially melts,
wherein the solder barrier layer is chosen such that it does not melt at the second temperature and such that the second metal of the molten alloy diffuses into an absorption layer so that the concentration of the first metal in the molten alloy further increases until the alloy isothermally solidifies at the second temperature and reaches the target ratio.

30. The method according to claim 28,
wherein, before bonding, the semiconductor body is grown on a growth substrate of the corresponding element, and
wherein, after producing the compound, the growth substrate is at least partially removed from the semiconductor body.

31. A semiconductor device comprising:
a semiconductor body; and
a carrier,
wherein the semiconductor body is connected to the carrier by at least one solder joint,
wherein at least one lateral surface of the at least one solder joint is free of traces of a cutting process,
wherein the solder joint comprises an alloy having a first and a second metal,
wherein a concentrations of the first metal and the second metal in the alloy are in a non-eutectic ratio, and
wherein the semiconductor device is a thin-film device in which a growth substrate of the semiconductor body is at least largely removed.

32. The semiconductor device according to claim 31,
wherein the lateral surface of the solder joint is exposed, and
wherein the lateral surface of the solder joint is concavely curved.

33. The semiconductor device according to claim 31, wherein the lateral surface of the solder joint is at least partially covered with a solid, electrically isolating material.

34. The semiconductor device according to claim 31, wherein the lateral surface of the solder joint is retracted at least in places with respect to a lateral surface of the semiconductor body and/or the carrier facing in the same direction as the lateral surface of the solder joint.

35. The semiconductor device according to claim 31,
wherein the semiconductor device is an optoelectronic device configured to emit or absorb electromagnetic radiation,
wherein, in plan view of a top side, the semiconductor device has a geometrical form different from a rectangle.

36. The semiconductor device according to claim 31,
wherein a concentration of the first metal and the second metal in the alloy is in each case at least 10 at-%,
wherein a first solder barrier layer is arranged between the solder joint and the semiconductor body and a second solder barrier layer is arranged between the solder joint and the carrier,
wherein each of the first and second solder barrier layers comprises at least one third metal, and
wherein a concentration of the third metal in the alloy is at most 10 at-%, the concentration of the first metal in the first and second solder barrier layers is at most 15 at-% and the concentration of the second metal in the first and second solder barrier layers is at least 10 at-%.

37. The semiconductor device according to claim 36,
wherein the first metal is Au,
wherein the second metal is Sn,
wherein the third metal is at least one of Ni, Pt, or Pd,
wherein the solder joint has a thickness between 100 nm and 5 μm, inclusive, and
wherein each of the first and second solder barrier layers has a thickness between 1 nm and 10 μm, inclusive.

38. A semiconductor device comprising:
a semiconductor body;
a carrier,
wherein the semiconductor body is connected to the carrier by at least one solder joint,
wherein the solder joint comprises an alloy having a first metal and a second metal with a concentration of the first metal and the second metal in the alloy being in each case at least 10 at-%, and
wherein the concentrations of the first metal and the second metal in the alloy are in a non-eutectic ratio; and
a first solder barrier layer arranged between the solder joint and the semiconductor body and a second solder barrier layer arranged between the solder joint and the carrier,
wherein each of the first and second solder barrier layers comprises at least one third metal, and
wherein a concentration of the third metal in the alloy is at most 10 at-%, the concentration of the first metal in the first and second solder barrier layers is at most 15 at-% and the concentration of the second metal in the first and second solder barrier layers is at least 10 at-%.

39. The semiconductor device according to claim 37,
wherein the first metal is Au,
wherein the second metal is Sn,
wherein the third metal is at least one of Ni, Pt or Pd,
wherein the solder joint has a thickness between 100 nm and 5 μm, inclusive, and
wherein each of the first and second solder barrier layers has a thickness between 1 nm and 10 μm, inclusive.
